(19) United States
(12) Patent Application Publication
(10) Pub. No.: US 2022/0023975 A1
(43) Pub. Date: Jan. 27, 2022

(54) UNSEALING METHOD OF SEMICONDUCTOR DEVICE PACKAGE AND UNSEALING DEVICE OF SEMICONDUCTOR DEVICE PACKAGE

(71) Applicant: Nippon Scientific Co., Ltd., Tokyo (JP)

(72) Inventors: Naoto OHTA, Tokyo (JP); Nobutoshi KOBAYASHI, Tokyo (JP)

(21) Appl. No.: 17/070,356

(22) Filed: Oct. 14, 2020

(30) Foreign Application Priority Data
Jul. 21, 2020 (JP) 2020-124442

(51) Int. Cl. B23K 26/402; B23K 26/14; H01L 23/10

(52) U.S. Cl. CPC B23K 26/402; B23K 2101/40; H01L 23/10; B23K 26/14

(57) ABSTRACT

According to an embodiment of the present disclosure, an unsealing method for exposing a semiconductor device package covered by a mold includes the steps of performing a first unsealing process and performing a second unsealing process. The first unsealing process includes a step for irradiating a part of the mold with a laser beam having at least one wavelength band so as to remove an organic resin included in the mold. The second unsealing process includes a step for applying a physical impact to a residue of the mold generated by the first unsealing process so as to expose the semiconductor device.

### CROSS REFERENCE TO RELATED APPLICATIONS

This application is based upon and claims the benefit of priority from the prior Japanese Patent Application No. 2020-124442, filed on Jul. 21, 2020, the entire contents of which are incorporated herein by reference.

### FIELD

An embodiment according to the present disclosure relates to an unsealing method of a semiconductor device package and an unsealing device of a semiconductor device package.

### BACKGROUND

An integrated circuit (IC) package (also called a semiconductor device package) covered by a mold may be unsealed by removing the mold for fault analysis of a defective product, checking the condition of a manufacturing process of a non-defective product, and the like.

Conventionally, chemical dissolution process using a strong acid (nitric acid, sulfuric acid, or a mixed solution thereof) and subsequent cleaning treatment with an organic solvent (isopropyl alcohol (IPA)-or ketone) have been used for unsealing the IC package covered by the mold (Japanese Unexamined Patent Application Publication No. 1994-021130).

When unsealing the IC package covered by the mold is unsealed, it is necessary to melt only the mold to suppress damage to metal used for a bonding wire, a lead frame, or a package substrate as much as possible. However, in the case of the unsealing process by the chemical solution described above, when the package is unsealed using the chemical solution such as nitric acid, sulfuric acid, or the mixture thereof, there is a problem that the chemical solution such as nitric acid, sulfuric acid, or the mixture thereof melts the metal used for the package substrate such as the bonding wire.

In addition, in recent years, there has been a tendency to avoid the use of chemicals such as acids and organic solvents, with an aim of reducing environmental impact due to chemical reduction and avoiding a risk of handling. At the same time, the semiconductor constituent the material has been changed for the purpose of cost reduction, and the number of the materials damaged by the acids have also been increasing. Therefore, a technique of unsealing the mold using a low-pressure O₂ plasma and an atmospheric-pressure O₂ plasma is also disclosed as an alternative to the unsealing the mold with acids (PCT International Publication No. WO 2018/047241).

### SUMMARY

According to an embodiment of the present disclosure, an unsealing method for exposing a semiconductor device package covered by a mold, includes the steps of performing a first unsealing process and performing a second unsealing process. The first unsealing process includes a step for irradiating a part of the mold with a laser beam having at least one wavelength band so as to remove an organic resin included in the mold. The second unsealing process includes a step for applying a physical impact to a residue of the mold generated by the first unsealing process so as to expose the semiconductor device.

In the above unsealing method of the semiconductor device package, the laser beam may include the laser beam having at least one of an infrared wavelength band and an ultraviolet wavelength band.

In the unsealing method of the semiconductor device package, the laser beam may include the infrared wavelength band laser beam and the ultraviolet wavelength band laser beam, the infrared wavelength band laser beam and the ultraviolet wavelength band laser beam may be irradiated so as to overlap in the part of the mold, and a beam diameter of the infrared wavelength band laser beam may be the same as or different from a beam diameter of the ultraviolet wavelength band laser beam.

In the unsealing method of the semiconductor device package, a pulse width of the infrared wavelength band laser beam may be different from a pulse width of the ultraviolet wavelength band laser beam.

In the unsealing method of the semiconductor device package, before irradiating with the laser beam, the temperature of the semiconductor device package may be controlled to be room temperature or higher and 100° C. or lower.

In the unsealing method of the semiconductor device package, the physical impact may be applied by high pressure jetting or ultrasonic cleaning of two fluids.

In the unsealing method of the semiconductor device package, the first unsealing process and the second unsealing process may be performed a plurality of times based on the unsealed condition of the semiconductor device package.

According to an embodiment of the present disclosure, an unsealing device for exposing a semiconductor device package covered by a mold includes a first unsealing unit configured to irradiate a part of the mold with a laser beam having at least one wavelength band to remove an organic resin included in the mold, and a second unsealing unit configured to apply a physical impact to the residue of the mold in the part of the mold so as to expose the semiconductor device.

In the unsealing device of the semiconductor device package, the laser beam may include the laser beam having at least one of the infrared wavelength band and the ultraviolet wavelength band.

In the unsealing device of the semiconductor device package, the laser beam may include the infrared wavelength band laser beam and the ultraviolet wavelength band laser beam, the infrared wavelength band laser beam and the ultraviolet wavelength band laser beam are irradiated so as to overlap in a part of the mold, and the beam diameter of the infrared wavelength band laser beam may be the same as or different from the beam diameter of the ultraviolet wavelength band laser beam.

In the unsealing device of the semiconductor device package, the pulse width of the infrared wavelength band laser beam may be different from the pulse width of the ultraviolet wavelength band laser beam.

In the unsealing device of the semiconductor device package, the temperature controller may be configured to control the temperature of the semiconductor device package from room temperature to 100° C.

In the unsealing device of the semiconductor device package, the physical impact may be applied by high pressure jetting or ultrasonic cleaning of two fluids.

The unsealing device of the semiconductor device package may further include an inspection unit configured to inspect the unsealing result of the semiconductor device package.

By using an embodiment of the present disclosure, it is possible to provide an unsealing device and a method for unsealing semiconductor device package that can reduce the time to unseal while minimizing the impact for the IC package component material. By using an embodiment of the present disclosure, it is possible to provide an unsealing device and a method for unsealing a semiconductor device package with a small environmental impact.

### BRIEF DESCRIPTION OF DRAWINGS

FIG. 1 is a schematic view of an IC package unsealing device according to an embodiment of the present disclosure;

FIG. 2 is a flow diagram of an unsealing method of the IC package according to an embodiment of the present disclosure;

FIG. 3 is a schematic view of an IC package unsealing device according to an embodiment of the present disclosure;

FIG. 4 is a schematic view of an IC package unsealing device according to an embodiment of the present disclosure;

FIG. 5A is an optical micrograph of the IC package surface after preprocessing in Example 1;

FIG. 5B is an optical micrograph of the IC package surface after 8 cycles of first unsealing process and second unsealing process in Example 1.

FIG. 6A is an optical micrograph of the IC package surface after preprocessing in the comparative example;

FIG. 6B is an optical micrograph of the IC package surface after 10 cycles of first unsealing process and second unsealing process in the comparative example;

FIG. 6C shows an optical micrograph of the IC package surface after 20 cycles of first unsealing process and second unsealing process in the comparative example; and

FIG. 7 is an electron micrograph of a portion of an IC package unsealed under the process condition of Example 1.

### DESCRIPTION OF EMBODIMENTS

Hereinafter, embodiments of the invention disclosed in the present application will be described with reference to the drawings. However, the present disclosure can be implemented in various embodiments without departing from the gist thereof, and should not be construed as being limited to the description of the following exemplary embodiments.

In the drawings referred to in the present embodiments, the same portions or portions having similar functions are denoted by the identical signs or similar signs (signs each formed simply by adding A, B, etc. to the end of a number), and a repetitive description thereof may be omitted. For the convenience of description, the dimensional ratio of the drawings may be different from the actual ratio, or a part of the configuration may be omitted from the drawings.

In the case of unsealing with the low-pressure plasma and the atmospheric-pressure plasma, it is inevitable that the constituent materials of some semiconductor devices is exposed by plasma, there is a case where the application range is limited. The processing speed for unsealing is slow, which may hinder the rapid response of the failure analysis.

Accordingly, the present disclosure provides an unsealing device of the semiconductor device package and an unsealing method of the semiconductor device package, which enables to shorten a time for unsealing while suppressing an effect on a constituent material of an IC package. the present disclosure provides also provide an unsealing device of the semiconductor device package and an unsealing method of the semiconductor device package having a reduced environmental impact.

In the embodiments of the present disclosure, an IC package 20 includes an IC chip 21, a mold 23, a lead frame 25, a bonding wire 27, and a bonding pad 29. The mold 23 covers the IC chip 21 (also referred to as a semiconductor device). The mold 23 may include an organic resin (e.g., an epoxy resin, an acrylic resin, or the like) or an inorganic particle (e.g., a silica filler). The lead frame 25 is connected to the IC chip 21 via the bonding wire 27 and the bonding pad 29. The lead frame 25 is provided so as to exposed partially. The IC package 20 is not limited to the structure described above. For example, in the IC package 20, the lead frame 25 may not be exposed. Alternatively, the IC package 20 may be mounted on a print substrate.

### First Embodiment

### (1-1. Configuration of IC Package Unsealing Device)

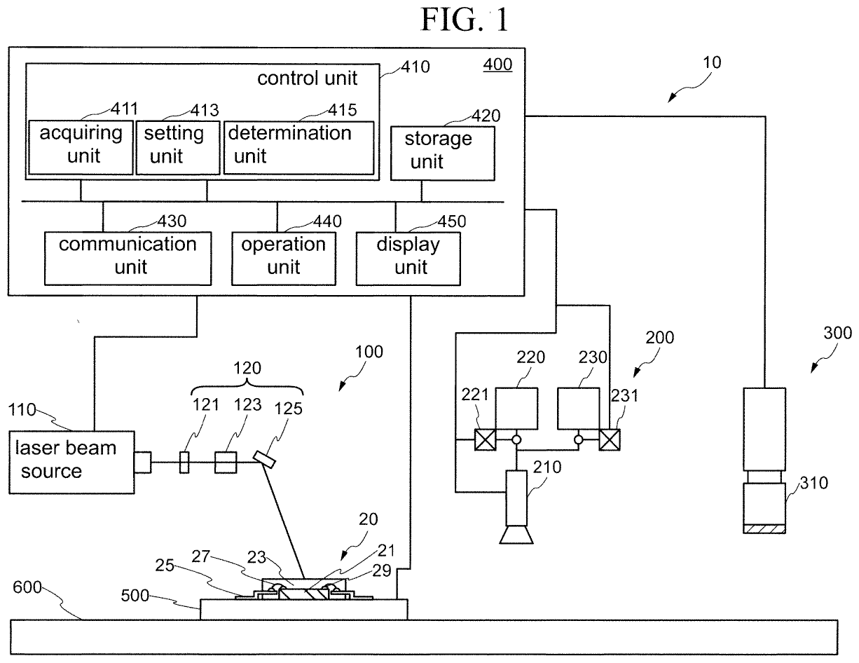

FIG. 1 is a schematic view of an IC package unsealing device 10 according to an embodiment of the present disclosure. The IC package unsealing device 10 includes a first unsealing process unit 100, a second unsealing process unit 200, an inspection unit 300, a control device 400, a positional controller 500, and a stage 600.

The first unsealing process unit 100 has a function of removing the organic resins in the mold 23. The first unsealing process unit 100 includes a laser beam source 110 and an optical element 120.

The laser beam source 110 irradiates a laser beam having at least one wavelength band. Preferably, the laser beam source 110 includes light having at least one wavelength band of infrared wavelength band (e.g., peak wavelength: 1064 nm) and ultraviolet wavelength band (e.g., peak wavelength: 355 nm).

In the present embodiment, a fiber laser is used as the laser beam source 110. The laser beam source 110 is not limited to the fiber laser, and a solid-state laser (YAG, glass, ruby, or the like), a liquid laser, a gaseous laser, a semiconductor laser, a free electron laser, or a chemical laser may be used. It is desirable to use a pulsed laser for the laser beam source 110. If the IC package 20 continues to be heated, the constituent materials of the IC package 20 may be loaded and damaged. When the pulsed laser is used, there is a non-irradiation time. Thus, the IC package 20 is appropriately cooled and prevented from being excessively heated. That is, the temperature rise of the IC package 20 can be easily controlled. The present embodiment is not limited to this, and a CW (Continuous Wave) laser may be used as appropriate depending on the power condition.

The optical element 120 directs the light emitted from the laser beam source 110 to an unsealing area of the IC package 20 (mold 23). In this example, the optical element 120 includes a shutter 121, a condenser lens 123, and a mirror 125.

The shutter 121 is provided to avoid unexpected radiation as a safety device. The condenser lens 123 controls the beam diameter of the laser beam to a condition set based on the energy density. The mirror 125 controls the optical path of the laser beam and directs the laser beam to the surface of the IC package 20.

The optical element 120 is not limited to the above-described configuration, and an optical element may be added as appropriate in accordance with an optical path. For example, a Galvano scanner may be used to control the scanning speed.

The second unsealing process unit 200 has a function to give physical impact to the surface of the mold 23 and remove residues of the mold. In this instance, the physical impact is given by high pressure injection of two fluids, liquid and gas. The second unsealing process unit 200 includes a nozzle 210, a liquid supply unit 220, and a gas supply unit 230.

The liquid supply unit 220 supplies liquid to the nozzle 210 through a solenoid valve 221 for a predetermined period of time. In this example, pure water is used as a liquid. When the pure water is used, the pure water may contain carbon dioxide from the viewpoint of countermeasures against electrostatic. When aluminum is used for the bonding pad, the pure water may contain a metal protectant in order to prevent corrosion. In this case, the metal protectant may comprise a surfactant. The liquid supply unit 220 may further include a water pressure adjuster or a temperature controller.

The gas supply unit 230 supplies gas to the nozzle 210 via a solenoid valve 231. In this example, compressed air is used as the gas. It is not limited to the compressed air, and an inactivating gas such as nitrogen or a rare gas may be used.

The inspection unit 300 inspects surface state of the IC package 20 after unsealing the mold 23 using an inspection device 310. In this example, an imaging device, specifically a CCD camera, is used as the inspection device 310. The inspection device 310 images surface of the IC package 20 and transmits the imaging photograph to the control device 400. In the present embodiment, an example of having an imaging device is shown, but the present disclosure is not limited thereto. For example, an optical microscope, a laser microscope, a reflectance measuring device, or the like may be used as the inspection device 310.

The control device 400 includes a control unit 410, a storage unit 420, a communication unit 430, an operation unit 440, and a display unit 450. The control unit 410, the storage unit 420, the communication unit 430, the operation unit 440, and the display unit 450 are connected via bus. The control device 400 controls the unsealing process of the IC package 20.

The control unit 410 may include a CPU (Central Processing Unit), an ASIC (Application Specific Integrated Circuit), an FPGA (Field Programable Gate Array), or other calculation processing circuitry. The control unit 410 controls processes for unsealing the IC package 20 by using a preset unsealing program of the IC package 20.

The storage unit 420 has a function as a database for storing an unsealing program of the IC package 20 and various kinds of data used in the unsealing program of the IC package 20. The storage unit 420 may be a memory, an HDD (Hard Disk Drive), an SSD (Solid State Drive), or other storage capable devices.

The communication unit 430 has a function of transmitting and receiving the unsealing process data between the respective processing unit in the IC package unsealing device 10. In the present embodiment, the control device 400, the first unsealing process unit 100, the second unsealing process unit 200, and the inspection unit 300 can respectively perform information communication via a network.

The operation unit 440 includes controllers, buttons, or switches. The operation unit 440 transmits data based on its operation to the control unit 410 by making operations such as moving up, down, left, or right, pressing, or rotating.

For a display device with a touch sensor (touch panel), the display unit 450 and the operation unit 440 may be located in the same location.

The display unit 450 is a display device such as a liquid crystal display or an organic EL display, and a display content is controlled by a signal input from the control unit 410. The display unit 450 may display the unsealing result transmitted from the inspection device 310. Users can grasp the progress situation of the unsealing process via the display unit 450.

In the present embodiment, the control unit 410 may include an acquiring unit 411, a setting unit 413, and a determination unit 415 as the internal configuration of the software.

The acquiring unit 411 acquires various information in the unsealing process of the IC package 20. In this example, the information about the IC package 20 to be unsealed is acquired. Specifically, the acquiring unit 411 acquires at least one of a thickness of the mold, a material of the mold, a material of the lead frame, a material of the bonding wire, and a material of the bonding pad. The acquiring unit 411 acquires unsealing information inspected by the inspection unit 300. In this case, the acquiring unit 411 may appropriately acquire various information via networks. The information acquired by the acquiring unit 411 is not necessarily limited to information acquired via networks. For example, the information may be acquired from a storage medium such as the SSD, the HDD, or the like, or the inspection unit 300 may be directly connected to the control device 400.

The setting unit 413 sets the unsealing condition based on the condition of the IC package 20, specifically, the mold 23. The set information may be transmitted to the first unsealing process unit 100 and the second unsealing process unit 200. The first unsealing process unit 100 and the second unsealing process unit 200 unseal the IC package 20 based on the set unsealing condition.

The determination unit 415 determines by calculation processing using the acquired information and information stored in the storage unit 420 in advance. In this example, the image of the IC package surface on which the unsealing process has been normally performed, which is stored in advance in the storage unit 420, is compared with the observation result (image) after the unsealing process to determine whether or not the unsealed area of the IC package 20 when viewed from the top reaches the preset unsealing area.

The determination unit 415 is not limited to the above process and may be determined based on data input by the user.

The positional controller 500 controls the position of the IC package 20 based on a control signal from the control device 400. The IC package 20 is arranged on the top surface of the positional controller 500. The positional controller 500 scans the IC package 20 in X direction and Y direction of a stage 600, and processing (scanning) of the IC package 20 is performed. The positional controller 500 may move the IC package 20 in the height direction (Z direction) in order to adjust the power distribution in the beam irradiated surface of the laser beam to an appropriate position.

In this example, the stage 600 is provided over the first unsealing process unit 100, the second unsealing process unit 200 and the inspection unit 300. The positional controller 500 can move from the first unsealing process unit 100 to the inspection unit 300.

### (1-2. Method for Unsealing the IC Package)

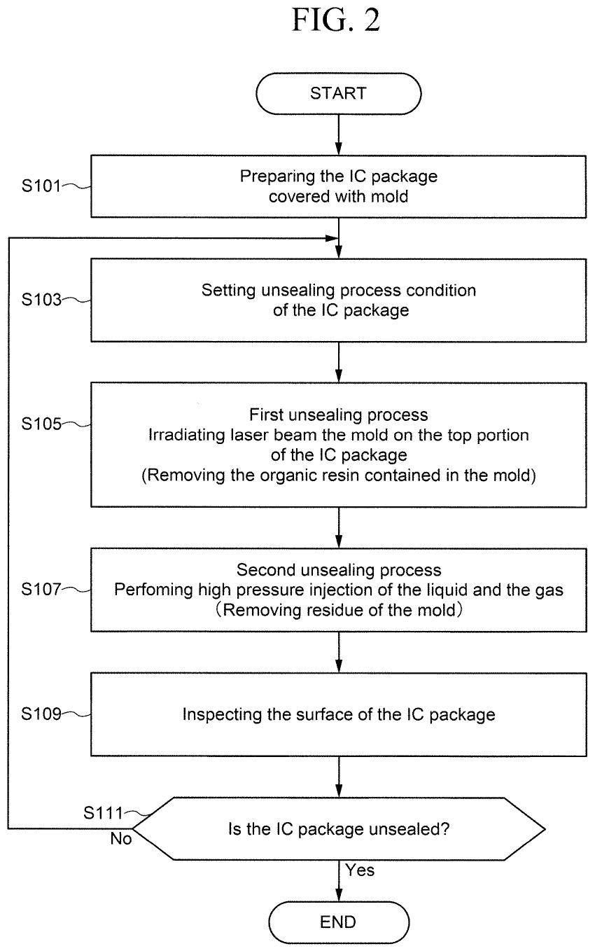

Next, an unsealing method of the IC package 20 will be described with reference to the drawings. FIG. 2 is a flow diagram showing an unsealing method of the IC package 20 according to the present embodiment.

First, the IC package 20 covered with mold is prepared (S101). The prepared IC package 20 is fixed on the positional controller 500 of the IC package unsealing device 10.

Here, the user may enter the information associated with the IC package 20 via the operation unit 440 of the control device 400. The acquiring unit 411 acquires the input information and stores the information in the storage unit 420.

The information about the IC package 20 may include, for example, at least one of the thickness of the mold 23 in the IC package 20, the material of the mold 23, the material of the lead frame 25, the material of the bonding wire 27, and the material of the bonding pad 29. Prior to the unsealing process, the surface of the IC package 20 may be evaluated in advance by the inspection unit 300.

The IC package 20 may be preprocessed before the unsealing process of the present embodiment is performed. The preprocessing may be performed by the same device. The preprocessing method is not particularly limited. For example, a laser ablation process may be performed as the preprocessing.

Next, an unsealing process condition of the IC package 20 is set (S103). The unsealing process condition may be set based on information associated with the IC package 20 described above. As the unsealing process condition, a first unsealing process condition in the first unsealing process unit 100 and a second unsealing process condition in the second unsealing process unit 200 are set. In this case, the repetition number of the first unsealing process and the second unsealing process may be set in advance.

As the first unsealing process condition, wavelength band of the laser beam, output intensity, frequency, pulse energy, beam diameter of the laser beam, irradiation position, irradiation range, scanning speed of the laser beam, number of scan, and irradiation time, or the like may be set. As the second unsealing process condition, processing time, type of liquid, and type of gas may be set. In particular, the output intensity (energy) of the laser beam may be set based on wavelength band of the laser beam, the beam diameter and the thickness of the mold. Because, when the wavelength band of the laser beam and the beam diameter, and the thickness of the mold are changed, the absorbed depth of the laser beam into the mold and the thermal effect on the IC chip 21 also changes.

When irradiating the laser beam, the irradiation may be performed under an atmosphere in which the oxygen concentration can be adjusted. By adjusting the oxygen concentration, the amount of combustion of the organic resin in the mold can be controlled.

Next, the first unsealing process is performed in the first unsealing process unit 100 (S105). The first unsealing process is performed by irradiating the laser beam toward the mold 23 on the top portion of the IC chip 21 with a laser beam using the first unsealing process condition described above. By the first unsealing process, the organic resin contained in the mold 23 is removed.

In the first unsealing process, an infrared wavelength band laser beam (peak wavelength: 1064 nm) is used in the present embodiment. For the infrared wavelength band laser beam, only the organic resin in the mold 23 can be removed by being burned by the energy of the laser beam. By setting an appropriate unsealing process condition, a damage to other components of the IC package 20 (e.g., the bonding wires 27) can be suppressed.

In the first unsealing process, an ultraviolet wavelength band laser beam (peak wavelength: 355 nm) may be used. In this case, since the absorption depth of the laser beam is the thickness (several micrometers) in the vicinity of the irradiation surface, the organic resin in the mold 23 can be locally burned and removed without affecting the entire IC package 20 thermally.

Next, the second unsealing process is performed in the second unsealing process unit 200 (S107). In the second unsealing process, high pressure injection of the liquid and the gas from the nozzle 210 is performed simultaneously in a processing area. Thus, the fine particle liquid is supplied to the surface of the IC packages 20. In this case, the fine particle liquid gives a physical impact on the residue of the mold (such as a silica filler). As a result, the residue of the mold 23 is removed and the IC chip 21 is exposed. In this example, pure water is used as the liquid and compressed air is used as the gas.

In the second unsealing process, the supply time of the liquid may be set shorter than the supply time of the gas by controlling the opening and closing of the solenoid valve 221 and the solenoid valve 231. Thus, since a time in which only the gas is supplied is provided, an unsealing area can be dried.

In the present embodiment, the first unsealing process and the second unsealing process described above may be repeatedly executed based on a preset repetition number in accordance with the thickness of the mold 23.

Next, the surface of the unsealing processed IC package 20 is inspected using the inspection device 310 of the inspection unit 300 (S109). In this case, it is determined whether the IC package 20 is unsealed using the unsealing result obtained by the inspection device 310 (S111). In this example, an area (also referred to as the first area) of the exposed portion of the IC chip 21 is calculated using the image of the IC package 20 viewed from the top face, which is imaged by the imaging device. Then, the first area is compared with an area of the IC chip 21 acquired in advance (also referred to as second area), and determined. In this case, it is determined whether or not the first area satisfies a predetermined condition. The predetermined condition is that the first area is equal to or greater than a predetermined ratio with respect to the second area. The determination process may be performed by inputting from the user, or may be performed automatically by the determination unit 415 of the control unit 410.

If it is determined that the IC package is not unsealed (S111; No), the unsealing process condition is set again (S103). If it is determined that the IC package has been unsealed (S111; Yes), the unsealing process terminates.

By using the present embodiment, a chemical solution such as strong acid may not be used for unsealing the mold. Therefore, the unsealing process of the mold can be performed quickly without affecting the constituent materials of the IC package 20 while suppressing environmental impact.

When the unsealing process of the IC package 20 is performed using the present embodiment, it is desirable that the thickness of the mold is 300 μm or less, more preferably 100 μm or less. Therefore, the IC package 20 may be preprocessed in advance as described above. As a result, the unsealing process can be performed more quickly without damaging the IC chip 21.

### Second Embodiment

In the present embodiment, an IC package unsealing device having a configuration different from that of the first embodiment will be described. Specifically, examples having a temperature adjuster for adjusting a temperature of the IC package will be described.

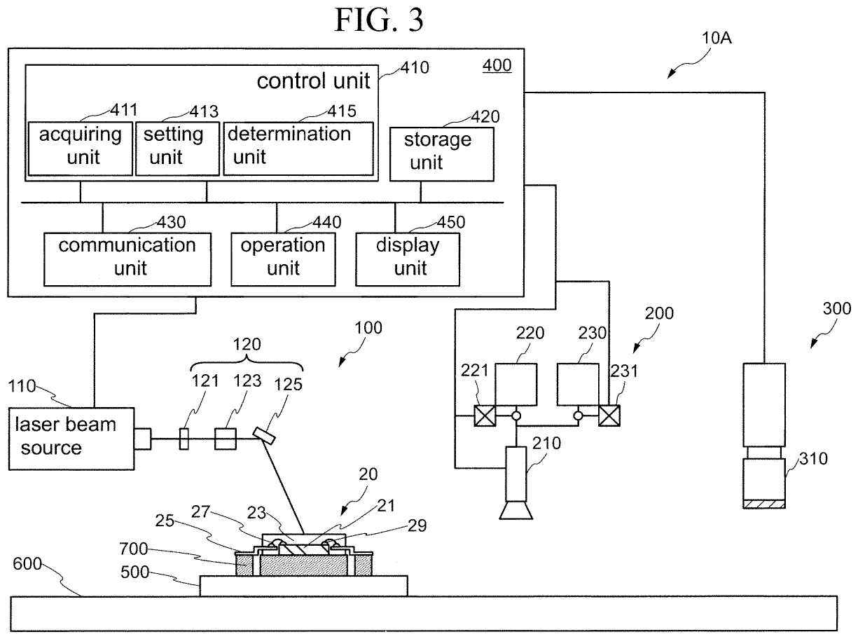

FIG. 3 is a schematic view of an IC package unsealing device 10A according to an embodiment of the present disclosure. As shown in FIG. 3, the IC package unsealing device 10A further includes a temperature adjuster 700 configured to adjust the temperature of the IC package 20 in addition to the first unsealing process unit 100, the second unsealing process unit 200, the inspection unit 300, the control device 400, the positional controller 500, and the stage 600.

The temperature adjuster 700 may independently adjust the temperatures of the mold 23 and the lead frame 25. Thus, it is possible to apply heat evenly to the mold 23 and the lead frame 25, the rapid temperature rise of the IC package 20 due to irradiation of the laser beam can be suppressed. Therefore, the thermal influence (damage) on the IC package 20 (in particular, the IC chip 21) can be suppressed. The heat applied by the temperature adjuster 700 prevents the heat of the unsealing area from spreading. Therefore, the unsealing process can be performed quickly. While suppressing thermal influence, it is desirable to control the temperature of the IC package (e.g., mold) in the range of room temperature (e.g., 20° C.) or higher and 100° C. or lower prior to laser irradiation from the viewpoint of quickly performing the unsealing process.

The temperature adjuster 700 may cool the mold 23 when the temperature of the mold 23 in the IC package 20 is higher than a predetermined temperature. For example, when the temperature of the mold 23 becomes 150° C. or higher, the IC chip 21 may be thermally affected. Therefore, cooling is desirable. The temperature adjuster 700 may cool the lead frame 25 within a temperature range in which the organic resin in the mold 23 can be burned, in order to protect the bonding wire 27 and the bonding pad 29. As a result, it is possible to mitigate the influence on the constituent material of the IC package.

In the present embodiment, the temperature of the mold 23 and the temperature of the lead frame 25 in the first unsealing process may be measured at any time. At this time, depending on the temperature, output conditions of the laser beam may be controlled.

### Third Embodiment

In the first embodiment of the present disclosure, the laser beam has one wavelength band, but the laser beam is not limited thereto. In the present embodiment, an example of performing unsealing process of the IC package using a laser beam having two wavelength bands will be described.

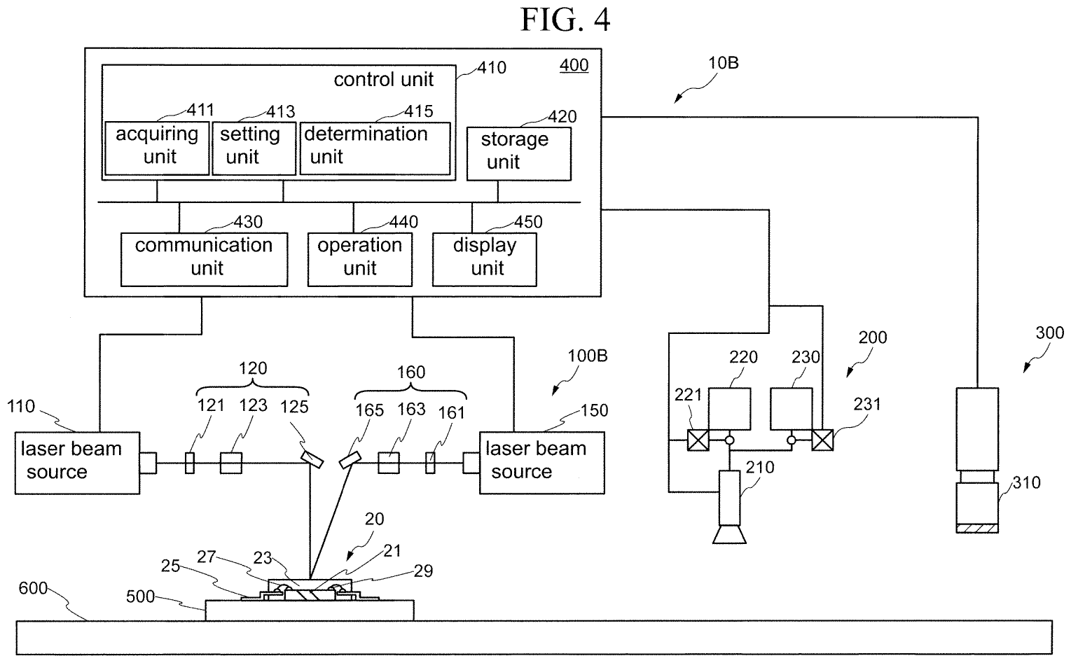

FIG. 4 is a schematic view of an IC package unsealing device 10B according to an embodiment of the present disclosure. As shown in FIG. 4, the first unsealing process unit 100B in the IC package unsealing device 10B further includes a laser beam source 150 and an optical element 160 in addition to the laser beam source 110 and the optical element 120. The optical element 160 includes a shutter 161, a condenser lens 163, and a mirror 165 as well as the optical element 120, but the necessary elements may be added or changed as appropriate. In the present embodiment, a part of the processing region is irradiated with an infrared wavelength band laser beam from the laser beam source 110, and an ultraviolet wavelength band laser beam is irradiated from the laser beam source 150 so as to overlap the irradiation region of the infrared wavelength band laser beam.

In this case, the beam diameter of the infrared wavelength band laser beam in the processing region may be the same as or different from the beam diameter of the ultraviolet wavelength band laser beam. Preferably, the beam diameter of the infrared wavelength band laser beam is larger than the beam diameter of the ultraviolet wavelength band laser beam. In the present embodiment, the mirror 125 may be disposed directly above the IC package 20. Thus, the power profile of the beam irradiated surface in the infrared wavelength band laser beam is easily adjusted to an appropriate position.

By using the present embodiment, when irradiating the ultraviolet wavelength band laser beam with locally concentrated, the portion that could not be burned due to insufficient thermal energy only with the ultraviolet wavelength band laser beam can be burned by adding the energy of the infrared wavelength band laser beam. As a result, the irradiated surface can be widely processed. Therefore, unsealing process rate can be improved.

In the present embodiment, the pulse width of the infrared wavelength band laser beam may be the same as or different from the pulse width of the ultraviolet wavelength band laser beam. For example, the pulse width of the infrared wavelength band laser beam may be longer than the pulse width of the ultraviolet wavelength band laser beam. Specifically, the pulse width of the infrared wavelength band laser beam is 5 times or more, more preferably 10 times or more of the pulse width of the ultraviolet wavelength band laser beam. In this case, the output energy of the infrared wavelength band laser beam may be reduced as compared with the case of using only the infrared wavelength band laser beam. As a result, it is possible to suppress a decrease of the mold temperature among the processing region in the IC package 20 and to prevent the mold from being excessively heated. Therefore, it is possible to effectively perform the unsealing process by using the infrared wavelength band laser beam of and the ultraviolet wavelength band laser beam of in combination, and it is possible to improve the unsealing process rate. Loads on the laser beam source can be reduced by reducing the output energy of the laser beam. Therefore, it is possible to prolong the life of the unsealing device.

If the pulse width of the infrared wavelength band laser beam and the pulse width of the ultraviolet wavelength band laser beam is the same or approximate, an irradiation timing of each laser beam may be staggered. As a result, at least one of the ultraviolet wavelength band laser beam and the infrared wavelength band laser beam is irradiated to the processed region of the IC package 20, so that it is possible to suppress a decrease in the mold temperature, and it is possible to effectively perform the unsealing process of the IC package 20. Therefore, the unsealing process rate of the IC package 20 can be improved.

In the present embodiment, an example using two laser beam source is shown, but three or more laser beam source may be used.

### Modification

Within the spirit of the present disclosure, it is understood that various modifications and modifications can be made by those skilled in the art and that these modifications and modifications also fall within the scope of the present disclosure. For example, as long as the gist of the present disclosure is provided, a person skilled in the art who adds, deletes, or changes the design of components or adds, omits, or changes the conditions of processes to each of the above-described embodiments is included in the scope of the present disclosure.

In the first embodiment of the present disclosure, an example is shown in which the inspection is performed after the first unsealing process and the second unsealing process, but the present disclosure is not limited thereto. For example, the unsealing condition may be inspected using the inspection device during the first unsealing process. Alternatively, the unsealing condition may be inspected using the inspection device during the second unsealing process. For example, the inspection device 310 may be arranged on the positional controller 500. As a result, it is possible to confirm the unsealing state at any time and to appropriately change the unsealing process condition.

In the first embodiment of the present disclosure, an example in which the unsealing process is performed using two fluids is described, but the present disclosure is not limited thereto. For example, the second unsealing process unit 200 may include an ultrasonic cleaning device. The ultrasonic cleaning device may include an ultrasonic vibrator which vibrates the water. In this case, the unsealing area of the IC package may be immersed into the ultrasonic cleaning device. As a result, the residue of the mold is removed by the physical impact of the water vibrated by the ultrasonic wave. The wet unsealing process surface of the IC package 20 may be dried by compressed air supplied from the gas supply unit 230.

The present disclosure is not limited to the above, and water vibrating ultrasonically may be sprayed onto the surface of the IC package.

In the first embodiment of the present disclosure, the example in which the stage 600 is provided across the first unsealing process unit 100, the second unsealing process unit 200, and the inspection unit 300, and the positional controller 500 moves from the first unsealing process unit 100 to the inspection unit 300 is shown, but the present disclosure is not limited thereto. For example, the positional controller 500 may be provided independently for each of the first unsealing process unit 100, the second unsealing process unit 200, and the inspection unit 300.

In the first embodiment of the present disclosure, an example is shown, in which an area of the exposed part of the IC chip imaged by the imaging device is determined, but the present disclosure is not limited thereto. For example, the remaining film thickness of the mold may be measured.

In the first embodiment of the present disclosure, an example is shown, in which a laser beam having a peak wavelength of 355 nm is used as an ultraviolet wavelength band laser beam, but the present disclosure is not limited thereto. For example, an excimer laser beam (peak wavelength: 193 nm or 248 nm), or a deep ultraviolet laser beam (peak wavelength: 266 nm) may be used. Although an example shown, in which a laser beam having a peak wavelength of 1064 nm is used as an infrared wavelength band laser beam, the present disclosure is not limited thereto. An infrared wavelength band laser beam having an appropriate peak wavelength may be used.

### EXAMPLES

### <1. Comparison of the IC Package Unsealing Results>

Hereinafter, the results will be described which compares the case of performing an unsealing process of the IC package using an embodiment of the present disclosure and the case of performing the unsealing process of the IC package by the atmospheric pressure O₂ plasma processing as a comparative example. The IC package of Example 1 and Comparative Example was pretreated by laser ablation process, respectively.

### (Processing Conditions of Example 1)

The unsealing process condition according to the Example 1 is as follows. The thickness of the mold in the processing region was 150 μm.

The First Unsealing Process
Laser wavelength: 1064 nm
Output intensity: 11 W to 14 W
Unsealing region: 1.5 mm×2 mm
Processing time per cycle: 4 min.

The Second Unsealing Process
Ultrasonic cleaning
Frequency: 30 kHz
Processing time: 1.5 min.

### (Processing Conditions of Comparative Example)

The unsealing processing conditions according to the comparative example are as follows. The thickness of the mold in the processing region was 150 μm.

The First Unsealing Process
Atmospheric pressure plasma processing
Gas flow rate: Ar 2000 sccm, O₂ 40 sccm
Voltage: 20 W
Processing time per cycle: 5 min

The Second Unsealing Process
Ultrasonic cleaning
Frequency: 30 kHz
Processing time: 1.5 min.
   <2. Observation Result of the IC Chip after Unsealing>

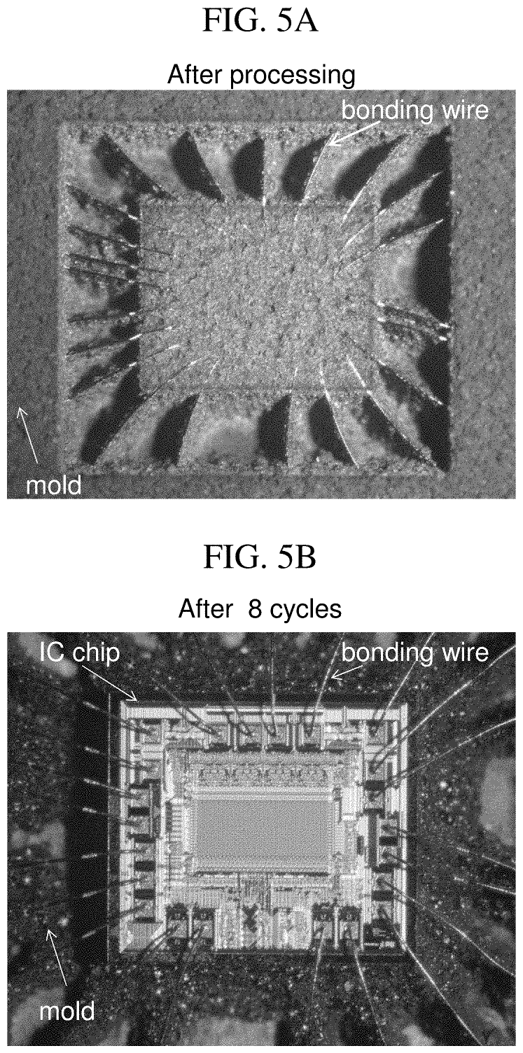

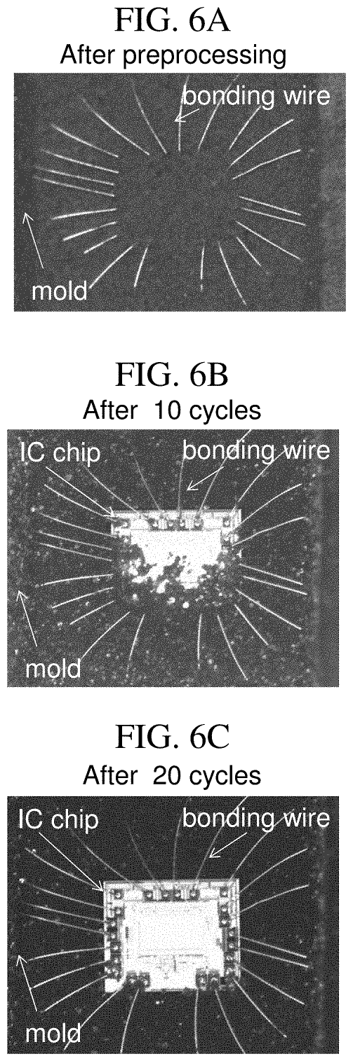

FIG. 5A shows an optical micrograph of the IC package surface after preprocessing in Example 1. FIG. 5B shows an optical micrograph of the IC package surface after 8 cycles of first unsealing process and second unsealing process in Example 1. FIG. 6A shows an optical micrograph of the IC package surface after preprocessing in the comparative example. FIG. 6B shows an optical micrograph of the IC package surface after 10 cycles of first unsealing process and second unsealing process in the comparative example. FIG. 6C shows an optical micrograph of the IC package surface after 20 cycles of first unsealing process and second unsealing process in the comparative example. Table 1 shows the time required for the IC chip to be exposed.

TABLE 1

| Example 1 | Comparative Example |
|---|---|
| 32 min. (8 cycles) | 130 min. (20 cycles) |

As shown in FIGS. 6A, 6B, 6C and Table 1, when the unsealing process was performed using the unsealing process condition of the comparative examples, the IC chip was not completely exposed in 10 cycles, and it took 20 cycles for the IC chip to be completely exposed. The unsealing process time at the end of 20 cycles was 130 minutes.

On the other hand, as shown in FIGS. 5A, 5B and Table 1, when the unsealing process was performed using the unsealing process condition according to Example 1, the IC chips were exposed by repeating the unsealing process for 8 cycles. In Example 1, the unsealing process time at the end of 8 cycles was 32 minutes.

Therefore, by applying the unsealing processing condition of Example 1 according to an embodiment of the present disclosure, it is possible to greatly reduce the unsealing process time of the IC package compared with the unsealing processing condition of the comparative example. When the unsealing process conditions of Example 1 were used, no residue in the unsealing area was observed.

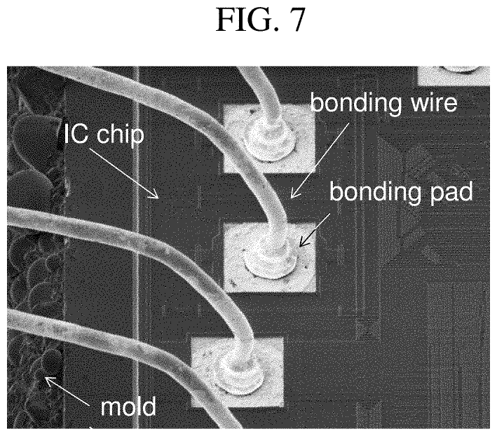

FIG. 7 shows an electronic micrograph of the bonding wire and the bonding pad in the unsealing IC package unsealed using the unsealing processing condition of Example 1 according to an embodiment of the present disclosure. As shown in FIG. 7, it was confirmed that neither the bonding wire nor the bonding pad of the IC chip after the unsealing process was damaged when the unsealing process was performed using the unsealing process conditions of Example 1. No operation abnormalities were observed in the IC chip.

What is claimed is:

1. An unsealing method for exposing a semiconductor device package covered by a mold, the unsealing device comprising the steps of:
performing a first unsealing process, the first unsealing process including a step for irradiating a part of the mold with a laser beam having at least one wavelength band so as to remove an organic resin included in the mold; and
performing a second unsealing process, the second unsealing process including a step for applying a physical impact to a residue of the mold generated by the first unsealing process so as to expose the semiconductor device.

2. The unsealing method according to claim 1, wherein
the laser beam includes a laser beam having at least one of an infrared wavelength band and an ultraviolet wavelength band.

3. The unsealing method according to claim 1, wherein
the laser beam includes an infrared wavelength band laser beam and an ultraviolet wavelength band laser beam,
the infrared wavelength band laser beam and the ultraviolet wavelength band laser beam are irradiated so as to overlap in the part of the mold, and
a beam diameter of the infrared wavelength band laser beam is different from a beam diameter of the ultraviolet wavelength band laser beam.

4. The unsealing method according to claim 3, wherein
a pulse width of the infrared wavelength band laser beam is different from a pulse width of the ultraviolet wavelength band laser beam.

5. The unsealing method according to claim 1, wherein
before irradiating with the laser beam, temperature of the semiconductor device package is controlled to be room temperature or higher and 100° C. or lower.

6. The unsealing method according to claim 1, wherein
the physical impact is applied by high pressure jetting or ultrasonic cleaning of two fluids.

7. The unsealing method according to claim 1, wherein
the first unsealing process and the second unsealing process are performed a plurality of times based on a condition of the semiconductor device package.

8. An unsealing device for exposing a semiconductor device package covered by a mold, the unsealing device comprising:
a first unsealing unit configured to irradiate a part of the mold with a laser beam having at least one wavelength band so as to remove an organic resin included in the mold; and
a second unsealing unit configured to apply a physical impact to the residue of the mold in the part of the mold so as to expose the semiconductor device.

9. The unsealing device according to claim 8, wherein
the laser beam includes a laser beam having at least one of the infrared wavelength band and the ultraviolet wavelength band.

10. The unsealing device according to claim 8, wherein
the laser beam includes the infrared wavelength band laser beam and the ultraviolet wavelength band laser beam,
an infrared wavelength band laser beam and an ultraviolet wavelength band laser beam are irradiated so as to overlap in the part of the mold,
a beam diameter of the infrared wavelength band laser beam is different from a beam diameter of the ultraviolet wavelength band laser beam.

11. The unsealing device according to claim 10, wherein
a pulse width of the infrared wavelength band laser beam is different from a pulse width of the ultraviolet wavelength band laser beam.

12. The unsealing device according to claim 8, further comprising:
a temperature controller configured to control the temperature of the semiconductor device package to be room temperature or higher and 100° C. or lower.

13. The unsealing device according to claim 8, wherein
the physical impact is applied by high pressure jetting or ultrasonic cleaning of two fluids.

14. The unsealing device according to claim 8, further comprising:
an inspection unit configured to inspect the unsealing result of the semiconductor device package.
